(19) United States
(12) Patent Application Publication
(10) Pub. No.: US 2004/0007660 A1
(43) Pub. Date: Jan. 15, 2004

(54) Optical sensor device for receiving light signal

(75) Inventors: Yin-Chun Huang, Hsin-Chu (TW); Shih-Zheng Kuo, Taipei (TW)

Correspondence Address: LOWE HAUPTMAN GILMAN & BERNER LLP, Suite 310, 1700 Diagonal Road, Alexandria, VA, 22314, US

(73) Assignee: UMAX DATA SYSTEMS INC.

(21) Appl. No.: 10/270,660

(22) Filed: Oct. 16, 2002

(30) Foreign Application Priority Data
Jul. 12, 2002 (TW) 091115608

(51) Int. Cl. H01L 31/00

(52) U.S. Cl. 250/214.1

(57) ABSTRACT

The present invention provides an optical sensor device for equally receiving light signals. The optical sensor device is composed of several optical sensor elements. The whole object of using the optical sensor elements to equally receive light signals depends on the formation of the optical sensor elements at an inclined plane on both sides of a substrate. Or, to make a central beaming pathway by equally increasing the height on both sides of the substrate.

### BACKGROUND OF THE INVENTION

1. Field of the Invention

This invention generally relates to the field of an optical sensor device. More particularly, the present invention relates to an optical sensor device, wherein the optical sensor device provides an angle or/and the substrate with different height regions.

2. Description of the Prior Art

The documents scanned by a general scanning system include color or monochrome photographs, artwork, and composed pages of text and graphics. The actual graphic image content of the scanned original document is referred to as an “original”.

In the use of a common scanner for scanning, an original on an opaque substrate is placed with the surface containing the original facing down on a flat transparent reference surface; the opaque substrate is typically glass. The original document is fixed on the surface, hereinafter referred to as a “scan line” is illuminated from below, and the light reflected from the scan line is directed through an optical system to form an image of the scan line on an optical sensor device, and converts the optical signal to an electronic representation of the scan line. When the desired scan line of the original is scanned, the optical sensor device along a direction hereinafter referred to as the “scanning axis” to scan the next line contiguously.

FIG. 1 illustrates the relation of a well-known optical sensor device, receiving light from various receiving angles. According to FIG. 1 the length from point A to A′ is labeled as Dₐ, and the length from point B to B′ is labeled as D_{b}, and length from point C to C′ is labeled as D_{c}. FIG. 2 shows a side view of a well-know optical sensor device 125, the optical sensor device 125 is formed by a plurality of optical sensor elements 127, and is arranged in a straight line.

When a light source illuminates the original 100, the beam 105, beam 110 and beam 115 are reflected or transmitted from the original 100. The beam 105 will project upon the surface of the optical sensor device 125 with angle θ^{A}, the beam 110 will also project upon the surface of the optical sensor device 125 with the angle θ^{B}, and the beam 115 will project upon the surface of the optical sensor device 125 with the angle θ^{c}. As mentioned above, the optical sensor device 125 is used to receive the light signal. Therefore, whether each charged-coupled device can receive reflected light with a constant average is important to generate a high quality image.

However, in a general scanning system of the prior art, the Dₐ and D_{c} is greater than D_{b}, the angle θ^{A}, angle θ^{c} is less than angle θ^{B}, as shown in FIG. 1. The chart 130 is used to represent the relation between the electronic representation and the included angle. The Y-axis of the chart 130 represents the electronic representation, and the X-axis of the chart 130 represents the received angle. As illustrated in chart 130, the reflection light 110 induces better electronic representation on the optical sensor device 125 than reflection light 105 and reflection light 115.

Furthermore, the evaluation data of MTF (modulation transfer function) of reflected light 110 is also better than reflected light 105 and reflected light 115. The MTF (modulation transfer function), a function that expresses the ability of an optical or electronic device to transfer signals faithfully as a function of the spatial or temporal frequency of the signal and is commonly known as a modulation transfer function (MTF). The MTF is the ratio of the percentage modulation of a sinusoidal signal leaving to that entering the device over the range of frequencies of interest.

Accordingly, it is necessary to provide an optical sensor device to equally receive a light signal through the optical sensor elements to obtain the light signals correct intensity.

### SUMMARY OF THE INVENTION

In accordance with the background of the foregoing invention, and the disadvantages in the prior art, the present invention provides an optical sensor device, to equally receive a light signal through the optical sensor elements to obtain the light signals correct intensity.

Accordingly, the object of the present invention is to make the optical sensor elements essentially receive a light signal at the same level.

Another object of the present invention is to receive a light signal with the optical sensor elements at different heights.

Another object of the present invention is to receive light signals with the optical sensor elements at different angles.

According to the objects mentioned above, the present invention provides an optical sensor device in a scanning system to receive light signals. The optical sensor device is composed of several optical sensor elements. The whole object of using the optical sensor elements to equally receive light signals depends on the formation of the optical sensor elements at an inclined plane on both sides of a substrate. Or, to make a central beaming pathway by equally increasing the height on both sides of the substrate. . Furthermore, another embodiment of the present invention combines two foregoing embodiments to obtain an optical sensor device that can be used to equally receive light signals.

### BRIEF DESCRIPTION OF THE DRAWINGS

The foregoing aspects and many of the attendant advantages of this invention will become more readily appreciated as the same becomes better understood by reference of the following detailed description, when taken in conjunction with the accompanying drawings, wherein:

FIG. 1 illustrates the correlation of a light pathway and the angle of inclination when receiving light by using a well-known optical sensor device.

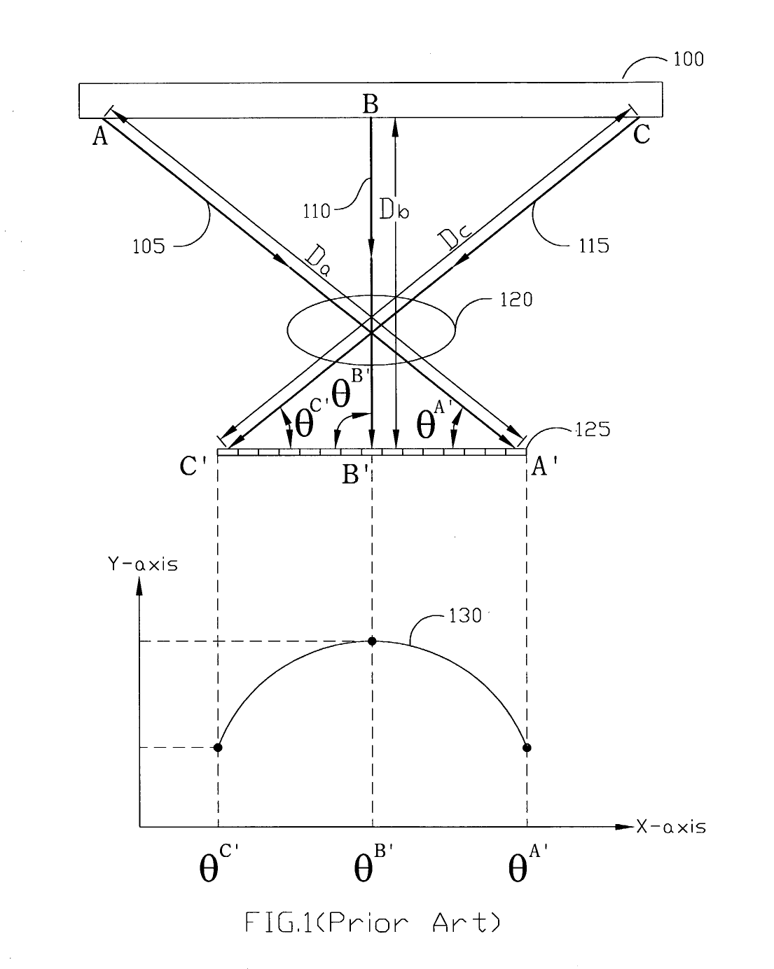

FIG. 2 illustrates a side view of a well-known optical sensor device.

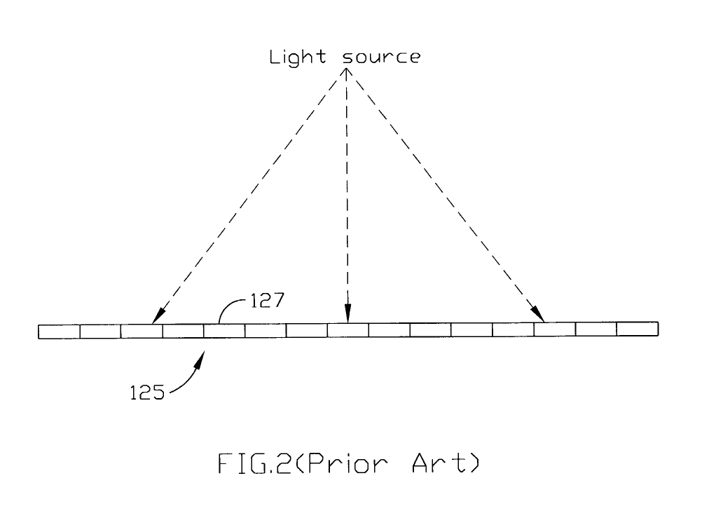

FIG. 3 illustrates a sectional view of an optical sensor device in the first preferred embodiment of the present invention.

FIG. 4 illustrates a sectional view of an optical sensor device in the second preferred embodiment of the present invention.

FIG. 5 illustrates a sectional view of an optical sensor device in the third preferred embodiment of the present invention.

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

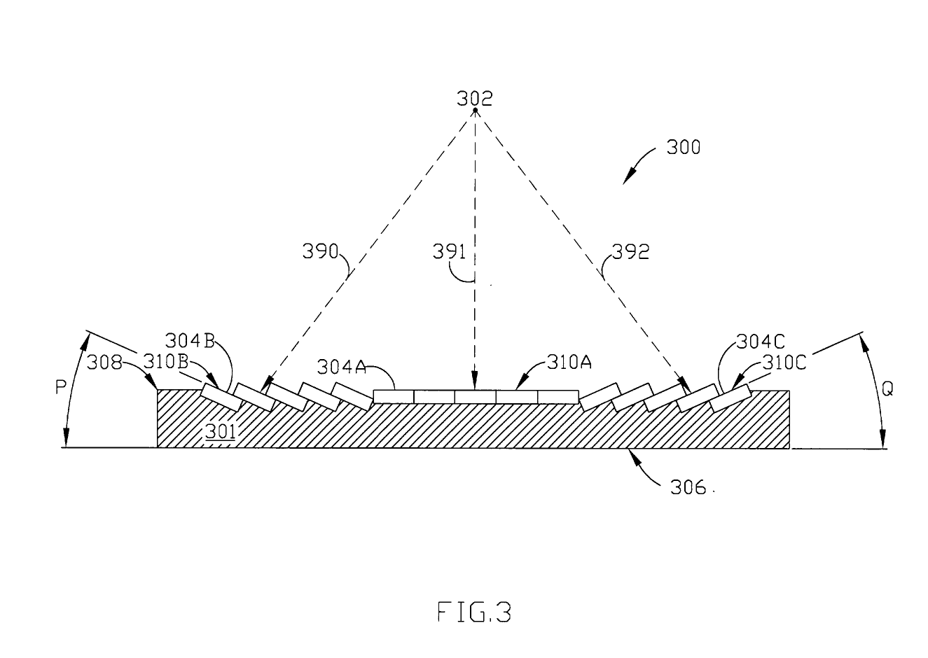

FIG. 3 illustrates a sectional view of an optical sensor device in the first preferred embodiment of the present invention, and it is used as an optical sensor device in a scanning system (for example, a optical scanning apparatus). As shown, an optical sensor device 300 is comprised of several optical sensor elements 304A, 304B, 304C, which lie on the surface of a substrate 301, wherein each of the optical sensor elements 304A, 304B, 304C can be a CCD (charged-coupled device) element, or CMOS (Complementary Metal-Oxide Semiconductor), or any other optical sensor.

As shown in FIG. 3, in this embodiment, the bottom surface 306 of the substrate 301 is plane, the optical sensor elements 304A, 304B, 304C lie on the surface 308 (or top) of a substrate 301. In this embodiment, the surface 308 of the substrate 301 is an approaching a plane (it is different from other embodiments with various heights, as shown in FIG. 3, 4), thus, the optical sensor elements 304A, 304B and 304C are essentially on the same plane (the surface 308).

The optical sensor element 304A on the central substrate 301 is arranged in a series on the same plane of the surface 308, thus, the optical sensor element 304A is parallel with the bottom surface 306. In regards to optical sensor elements 304B, 304C, they are adhered at both sides of substrate 301, with a incline on surface 308, in another word, the surfaces 310B, 310C of the optical sensor elements 304B, 304C have angles greater than zero P, Q, between the bottom surface 306. In this embodiment, the angles P, Q are fixed, but in fact, each optical sensor element 304B, 304C can adjust the angles P, Q for surfaces 310A, 310B, 310C thus creating the preferred angle to receive a light signal.

In accordance with the structure of the first preferred embodiment, the optical sensor elements 304A, 304B and 304C equally receive the light signal. The light from light source 302 (only shown in the figure are light signals 390, 391, 392) is essentially vertical to the optical sensor elements 304A, 304B, and 304C. Thus, optical sensor elements 304B and 304C have been enhanced to equally receive the light signal on both sides. The foregoing light source 302 can be a reflection or transmission.

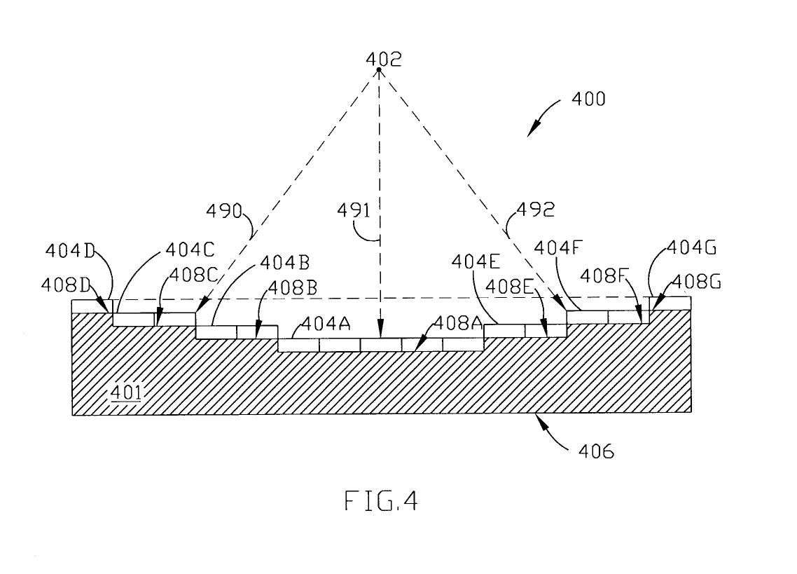

FIG. 4 illustrates a sectional view of an optical sensor device in the second preferred embodiment of the present invention; it is used as an optical sensor device in a scanning system (for example, a optical scanning apparatus). As shown in FIG. 4, an optical sensor device 400 is comprised of several optical sensor elements 404A-404G, which are adhered on the surface of a substrate 401, wherein each of the optical sensor elements 404A-404G can be a CCD (charged-coupled device) element, or CMOS (Complementary Metal-Oxide Semiconductor), or any other optical sensor.

As shown in FIG. 4, in this embodiment, the surface of the substrate 401 is divided in to several area surfaces 408A-408G, each area surface is at a different height. In this embodiment, both sides of the surface are formed to a ladder-shaped, the height around the outside surface is higher than the level of the central surface, for example, the height of area surface 408C is higher than the level of area surface 408B. The optical sensor elements 404A-404G respectively adhere to the area surface 408A-408G (or top) of substrate 401.

The optical sensor element 404A on the central area 408A of the substrate 401 is arranged in a series on the same plane of the surface area 408A, thus, the optical sensor element 404A is essentially parallel with the bottom surface 406. In regards to the optical sensor elements 404B-404G, they are also arranged in a series on the surface area 408B-408G respectively.

In accordance with the structure of the second preferred embodiment, the light pathways from light source 402 (only shown the light signal 490, 491, 492 in the figure) are essentially equal, thus, the optical sensor elements 404A-404G equally receive the light signal. The foregoing light source 402 can be a reflection or transmission.

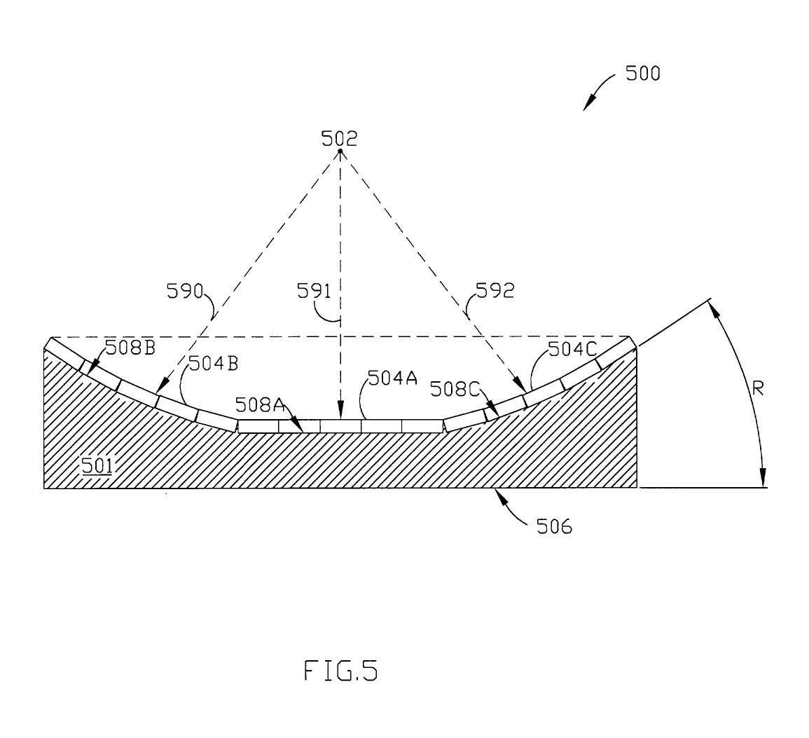

FIG. 5 illustrates a sectional view of an optical sensor device in the third preferred embodiment of the present invention; it is used as an optical sensor device in a scanning system (for example, an optical scanning apparatus). This preferred embodiment mainly combines the first embodiment (FIG. 3); therein the optical sensor elements are provided at angles, and the second embodiment (FIG. 4); therein the optical sensor elements are provided in areas at various levels of height. Thus, it forms an optical sensor device with the features of having areas at various levels of height and angles.

As shown in FIG. 5, an optical sensor device 500 is comprised of several optical sensor elements 504A, 504B and 504C, which are adhered on the surface of a substrate 501, the optical sensor elements 504A, 504B and 504C can be CCD (charged-coupled device) elements, or CMOS (Complementary Metal-Oxide Semiconductor), or any other optical sensors.

As shown in FIG. 5, in this embodiment, the surface of the substrate 501 is divided into several area surfaces 508A-508C (in this embodiment, it is divided to three area surface), each area surface level is at a different height. In this embodiment, the both sides of surface area 508B, 508C have an angle of inclination R, which is greater than zero between the bottom surface 506, with the result that form an inner curved surface 508B or 508C. The optical sensor elements 504A-504C are adhered in a series on the surface area 508A-508C of the substrate 501 respectively.

The optical sensor element 504A on the central area 508A of the substrate 501 is arranged in a series on the same plane of the surface area 508A, thus, the optical sensor element 504A is essentially parallel with the bottom surface 506. In regards to optical sensor elements 504B and 504C, they are also arranged in a series on the respective surface area 508B and 508C.

In accordance with the structure of the third preferred embodiment, the light pathways from light source 502 (only shown the light signal 590, 591, 592 in the figure) are essentially equal and essentially vertical with the optical sensor elements 504A, 504B, and 504C. Thus, the optical sensor elements 504A-504C on average, equally receive the light signal as a result of the enhancement of optical sensor elements 504B, 504C. The foregoing light source 402 can be a reflection or transmission.

As mentioned above, although, the central area surface 508A is plane in this third preferred embodiment, it can be modified to make the area surfaces 508A-508C to form a curved surface.

Although specific embodiments have been illustrated and described, it will be obvious to those skilled in the art that various modifications may be made without departing from what is intended to be limited solely by the appended claims.

What is claimed is:

1. An optical sensor device, comprising:
a substrate, wherein said substrate has a bottom surface; and
a plurality of optical sensor elements, said plurality of optical sensor elements are adhered on a top surface of said substrate, wherein a portion of said optical sensor elements are at an angle greater than zero degree with respect to the bottom surface.

2. The optical sensor device according to claim 1, wherein said optical sensor elements are essentially on the same level.

3. The optical sensor device according to claim 1, wherein said optical sensor element is charged-coupled device (CCD).

4. The optical sensor device according to claim 1, wherein said optical sensor element is CMOS (Complementary Metal-Oxide Semiconductor).

5. An optical sensor device, comprising:
a substrate, the surface of said substrate at least includes two areas, wherein the surface of said areas is on different level height respectively; and
a plurality of optical sensor elements, said plurality of optical sensor elements are adhered on the surface of said substrate.

6. The optical sensor device according to claim 5, wherein each said area surfaces is parallel, and the level height of around the surface of said substrate is higher than the level height of the central surface of said substrate.

7. The optical sensor device according to claim 5, wherein said optical sensor element is charged-coupled device (CCD).

8. The optical sensor device according to claim 5, wherein said optical sensor element is CMOS (Complementary Metal-Oxide Semiconductor).

9. An optical sensor device, comprising:
a substrate, said substrate has a bottom surface, and the surface of said substrate at least includes two surface areas, wherein said surface areas are on different level height respectively; and
a plurality of optical sensor elements, said plurality of optical sensor elements are adhered on the surface of said substrate, wherein a portion of said optical sensor elements have a angle greater than zero with respect to the bottom surface.

10. The optical sensor device according to claim 9, wherein one of said surface areas has inclination.

11. The optical sensor device according to claim 9, wherein the surface of said substrate includes three joined surface areas, both side of said three joined surface areas have inclinations.

12. The optical sensor device according to claim 9, wherein the around area of said substrate surface has curved surface.

13. The optical sensor device according to claim 9, wherein said optical sensor element is charged-coupled device (CCD).

14. The optical sensor device according to claim 9, wherein said optical sensor element is CMOS (Complementary Metal-Oxide Semiconductor).
